(19) United States
(12) Patent Application Publication
(10) Pub. No.: US 2013/0025683 A1
(43) Pub. Date: Jan. 31, 2013

(54) PHOTOELECTRIC ELEMENT

(71) Applicants: Takashi Sekiguchi, Osaka (JP); Takeyuki Yamaki, Nara (JP); Mitsuo Yaguchi, Osaka (JP); Michio Suzuka, Osaka (JP); Hiroyuki Nishide, Tokyo (JP); Kenichi Oyaizu, Tokyo (JP); Fumiaki Kato, Tokyo (JP); Satoko Kambe, Osaka (JP)

(72) Inventors: Takashi Sekiguchi, Osaka (JP); Takeyuki Yamaki, Nara (JP); Mitsuo Yaguchi, Osaka (JP); Michio Suzuka, Osaka (JP); Shingo Kambe, Osaka (JP); Hiroyuki Nishide, Tokyo (JP); Kenichi Oyaizu, Tokyo (JP); Fumiaki Kato, Tokyo (JP)

(21) Appl. No.: 13/575,395

(22) PCT Filed: Feb. 4, 2011
(86) PCT No.: PCT/JP2011/052339

§ 371 Date: Oct. 15, 2012

(30) Foreign Application Priority Data
Feb. 5, 2010 (JP) 2010-024413

(51) Int. Cl. H01L 51/44

(52) U.S. Cl. 136/263

(57) ABSTRACT

The present invention provides a photoelectric conversion element comprising: an electron transport layer which has an excellent electron transport property and a sufficient reaction interface, and having excellent conversion efficiency. In the present invention, a photoelectric conversion element comprises: a first electrode; a second electrode; a stack of an electron transport layer and hole transport layer, the stack being interposed between the first electrode and the second electrode; an electrolyte solution; and a conductive agent; the electron transport layer containing an organic compound having a redox moiety causing repetitive oxidation-reduction reactions, the electrolyte solution being selected to give stable reduction condition of the redox moiety, the organic compound and the electrolyte solution being cooperative to form a gel layer. Wherein the conductive agent is present within the gal layer and kept at least partly in contact with the first electrode.

### TECHNICAL FIELD

The present invention relates to a photoelectric conversion element that converts electricity into light, or light into electricity.

### BACKGROUND ART

Recently, photoelectric conversion element have been used as, for example, a power generation element such like a photocell and a solar cell which convert light energy into electrical energy; a luminescent element such like an organic EL element; a display element such like an electrochromic display cell and an electronic paper; and a sensing element scenting temperature, light and the like.

Electron-transport layer in the photoelectric conversion element requires a high electron transport property. In the electron transport layer, it is even more important to be a large size of the area of reaction interface to generate electrons by the energy given from the outside and to inject electrons from the outside. Such above electron-transport layer comprises metal, organic semiconductor, inorganic semiconductor, conductive polymer, and conductive carbon.

In the photoelectric conversion element, the electron-transport layer comprises organic compounds such like fullerene, perylene derivative, polyphenylene vinylene derivative or pentacene for electron transportation. Thus, the conversion efficiency of photoelectric conversion elements are being improved with improving the ability of electron transportation in the electron transport layer (see Non-Patent Document 1 for fullerene; Non-Patent Document 2 for perylene derivative; Non-Patent Document 3 for polyphenylene vinylene derivative; and Non-Patent Document 4 for pentacene).

In addition, it is disclosed that molecular element type solar cell is formed as the structures that a thin film formed by chemical bond between the electron donor molecule (donor) and the electron acceptor molecule (acceptor) is laid on a base material (see Non-Patent Document reference 5).

### PRIOR ART DOCUMENTS

### Patent Documents

Patent Document 1; Japanese Patent Publication No. 10-290018.
Patent Document 2; Japanese Patent Publication No. 10-112337.

### Non-Patent Documents

Non-Patent Document 1; P. Peumans, Appl. Phys. Lett., No. 79, 2001, page 126.
Non-Patent Document 2; C. W. Tang, Appl. Phys. Lett., No. 48, 1986, page 183.
Non-Patent Document 3; S. E. Shaheen, Appl. Phys. Lett., No. 78, 2001, page 841.
Non-Patent Document 4; J. H. Schon, Nature (London), No. 403, 2000, page 408.
Non-Patent Document 5; Hiroshi Imahori, Shun-ichi Fukuzumi, “Prospects of molecular solar cells”, July 2001 issue of Chemical Industry, page 41.

However, the electron-transport layer disclosed in above indicated Non-Patent Documents dose not still satisfy both the sufficient area of interface for which electron-transport layer acts and the sufficient electron transport property. Consequently, it is expected that electron-transport layer has both the more excellent property of electron transport and the sufficient large interface for electron transport.

For example, when the electron transport layer contains the organic compound such like fullerene, it is difficult to further improve the conversion efficiency because the electron charge recombination occurs easily, and because the effective diffusion distance is not sufficient. The effective diffusion distance is identified as the distance that charge carriers arrive at the electrode after charge separation. In short, it is thought that the conversion efficiency of the element increases with greater effective diffusion distance. When the electron-transport layer contains the inorganic compound such like titanium oxide, the interface area for charge separation is not sufficiently. The conversion efficiency is not sufficient because the electron conductive potential is primarily determined by constituent elements and affects to the open-circuit voltage.

For example, Patent Document 1 discloses, as shown in FIG. 4, another way of increasing the efficiency of photoelectric conversion element, In this case, the conductivity of the semiconductor layer 11 is ensured by mixing the conductive particles 13 between the dye-sensitized semiconductor particles 12. The dye-sensitized semiconductor particles 12 are contained in the semiconductor layer 11. Herein, the electrode 4 is formed on the substrate 7, and has the semiconductor layer 11 on its own surface. However, in above mentioned method, it cannot expect the increasing of photo-electric conversion efficiency because the electron transportation is prevented by the trapping of the conductive particles 13 having high conductivity when electrons excited by incident light transfer in the mixture film containing the dye-sensitized semiconductor particles 12 and the conductive particles 13.

Patent Document 2 describes the method for decreasing an electrical resistance at the reaction interface with forming an integrated structure of the conductive substrate and the oxidized film by the oxidizing an anode of the metal surface and the coating that surface with the porous metal oxide. However, above method has a further problem of increasing the costs because it needs to use metal titanium as the substrate.

### DISCLOSURE OF THE INVENTION

In view of the above points, the present invention has a purpose to provide a photoelectric conversion element comprising an electron transport layer that has an excellent electrons transportation property and an sufficient wide reaction interface, in which the photoelectric conversion element further decreases the resistance loss and has more excellent photo-electric conversion efficiency.

In the present invention, a photoelectric conversion element comprises: a first electrode; a second electrode; a stack of an electron transport layer and hole transport layer, the stack being interposed between the first electrode and the second electrode; an electrolyte solution; and a conductive agent; the electron transport layer comprising an organic compound having a redox moiety causing repetitive oxidation-reduction reactions, the electrolyte solution being selected to give stable reduction condition of the redox moiety, the organic compound and the electrolyte solution being cooperative to form a gel layer. Wherein the conductive agent is present within the gal layer and kept at least partly in contact with the first electrode.

In the present invention, the conductive agent preferably has a roughness factor in the range of 5 to 2000.

In the present invention, the conductive agent preferably comprises a coupled mass of conductive particles.

In the present invention, the conductive agent preferably comprises conductive fibers.

In the present invention, the conductive agent preferably has an average outside diameter in the range of 50 nm to 1000 nm.

In the present invention, the conductive fibers preferably have a void ratio of 50% to 95%.

In the present invention, the conductive fibers preferably have an average fiber length to average fiber diameter ratio of at least 1000.

In the present invention, it is able to obtain the photoelectric conversion element having a lower resistance loss and more excellent photo-electric conversion efficiency by the comprising an excellent electrons transportation property and a sufficient wide reaction interface in the electron transport layer.

### BRIEF DESCRIPTION OF THE DRAWINGS

FIG. 1 represents an example of embodiment in the present invention, and each of A, B and C is a schematic cross-sectional view and a magnified portion.

FIG. 2 shows an electron micrograph of the porous conductive film in Example 5.

FIG. 3 shows a schematic cross-sectional view to explain an example of the embodiment in the present invention.

FIG. 4 shows partial magnification of a schematic cross-sectional view in prior art.

### BEST MODE FOR CARRYING OUT THE INVENTION

The below description is about the embodiments of the present invention.

In the photoelectric conversion element, an electron transport layer 1 and a hole transport layer 5 are sandwiched between one pair of electrodes 4,6 (hereinafter, named as first electrode 4 and second electrode 6, respectively). The electron transport layer 5 comprises an organic compound having redox moiety causing repetitive oxidation-reduction reactions. The organic compound swells by comprising an electrolyte solution and is formed as gel layer 2. A conductive agent 3 is present within the gal layer 2 and kept at least partly in contact with the first electrode 4. Thus, the electron transport layer 1 has a wide reaction interface because the gel layer 2 is formed as the electron transport layer 1 comprising the organic compound and the electrolyte solution. Consequently, the photoelectric conversion element has an improved photo-electric conversion efficiency with improvement of electron transportation property because the conductive agent 3 is present within the gal layer 2 and kept at least partly in contact with the first electrode 4.

Like above, the photoelectric conversion element has the improved photo-electric conversion efficiency with improvement of the electron transportation property of the electron transportation layer 1 the reason why the electron transportation layer 1 has the wide reaction interface with the formation to the gel layer 2 by the comprising the organic compound and the electrolyte solution and the reason why the conductive agent 3 presences within gel layer 2.

The conductive agent preferably has a roughness factor in the range of 5 to 2000. In this case, the conductive efficiency is improved by suppressing the side reaction on surface of the conductive agent 3 together with increasing of collecting effect in the gel layer 2. The roughness factor is described as the ratio of an actual surface area to a projected area. This projected area corresponds to the projected area of the gel layer 2. As an explanation of the actual surface area, if the conductive agent 3 consists of n conductive particles in which each of the conductive particles has the diameter defined as r, the conductive agent 3 has the actual surface area calculated as n×4×π×r². When it is not ale to calculate the actual surface area of the conductive agent 3 easy by the shape of the conductive agent 3, the actual surface area can be obtained by nitrogen adsorption method.

The conductive agent 3 may comprise a coupled mass of the conductive particles. In this case, the conversion efficiency is further increased by improvement of the electron transport property because the coupled mass (conductive particles) is mixed within the gel made from the organic compound and the electrolyte solution which are comprised in the electron transportation layer 1.

In another embodiment, the conductive agent 3 may comprise conductive fibers. In this case, the conductive agent 3 has high intensity because of the conductive fibers. Consequently, the conductive agent 3 is formed easily with the high void rate. The electron transportation layer 1 and/or the gel layer 2 are formed easily within the void of the conductive agent 3.

The conductive fibers preferably have an average outer diameter in the range of 50 nm to 1000 nm. This average outer diameter is calculated from the average value of outer diameter (30 conductive fibers used for) by the measurement via the electron microscopy such like SEM. In this case, the conductive agent 3 is formed with higher intensity and void rate. Consequently, the photoelectric conversion element has higher output by the large increasing of specific surface area of the conductive agent 3.

The conductive agent 3 comprising the conductive fibers may have a void rate in the range of 50% to 95%. In this case, the electron transportation layer 1 has more excellent electron transport property by presence of the conductive agent 3 in a sufficient amount within gel layer 2. Consequently, the electron transportation layer 1 has more excellent conversion efficiency because the gel layer 2 has a sufficient field for the photo-electric conversion by presence of the organic compound and the electrolyte solution in a sufficient amount within the void of the conductive agent 3.

The conductive fibers preferably have an average fiber length to average fiber diameter ratio of at least 1000. In this case, the conductive fibers are easily stacked in the state arranged to surface direction of electrode 4. Thus, the conversion efficiency is further improved by increasing of the void rate of conductive agent 3 comprising the conductive fibers. The average fiber length and the average fiber diameter are defined as an average value of fiber (conductive fibers) length and an average value of fiber (conductive fibers) diameter, respectively, (30 conductive fibers used for) by the measurement via the electron microscope such like SEM. In measurement of fiber diameter, it needs to exclude a knotting position of the conductive fiber.

The gel layer 2 has a sensitizer dye, and the sensitizer dye may be immobilized to the organic compound comprised in gel layer 2 via physical or chemical action. In this case, electron transport efficiency between the sensitizer dye and the organic compound is improved by approach of the sensitizer dye and the organic compound.

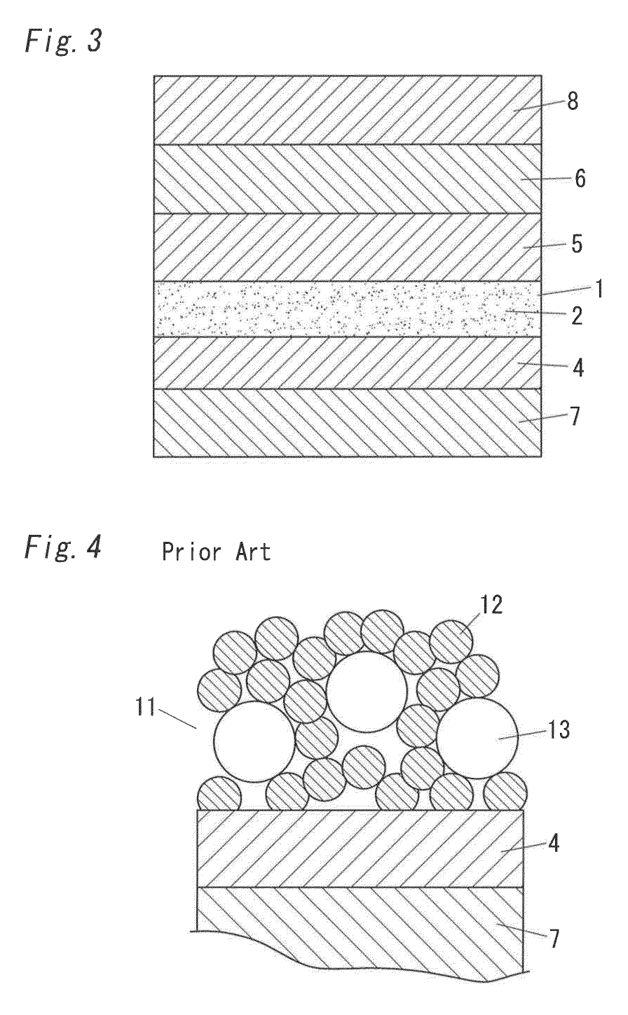

FIG. 3 shows one example of the photoelectric conversion element. One pair of base materials 7,8 (hereinafter, named as first base material 7 and second base material 8, respectively) are arranged in face to face. The first electrode 4 is disposed on an inner surface of the first base material 7, and the second electrode 6 is disposed on an inner surface of the second base material 8. Consequently, the first electrode 4 and the second base material 8 are arranged in phase to phase. The electron transport layer 1 is formed on a surface of the first electrode 4 in opposite direction of the first base material 7. A hole transport layer 5 is formed on a surface of the second electrode 6 in opposite direction of the second base material 8. The electron transport layer 1 comprises the organic compound having a redox moiety. The electron transport layer 1 is formed as gel layer 2 with comprising the organic compound and the electrolyte solution. The conductive agent 3 is comprised within the gel layer 2.

For example, the first electrode 7 has an insulation performance by forming with glass, light-transmissive film and the like. The first electrode 4 is formed by stacking a conductive material such like the conductive fibers and the conductive particles on the insulative first base material 7. A preferable examples of the conductive material are metal such like platinum, gold, silver, copper, aluminum, rhodium, and indium; carbon; conductive metal oxide such like indium-tin composite oxide, tin oxide doped with antimony, tin oxide doped with fluorine; composite of the metal and compound; and material obtained by coating on the metal and/or compound with silicon oxide, tin oxide, titanium oxide, zirconium oxide, aluminum oxide and the like. It is preferable that the electrode 4 has low surface resistance. For example, the surface resistance is preferably defined as 200Ω/□ or less and more preferably as 50Ω/□ or less. Although the lowest value of the surface resistance is especially not limited, but the lowest value is generally 0.1Ω/□.

In the case of forming the first electrode 4 on the first base material, if the base material 7 needs to have a translucency in using for photo-electric conversion element such like power generation element, light emitting element, photo sensor and the like, the base material 7 preferably has high light transmittance. The light transmittance, in 500 nm of wavelength, of the base material 7 is preferably defined as at least 50%, and more preferably as at least 80%. The first electrode 4 preferably has a thickness in the range of 0.1 to 10 μm. By having of the thickness within this rang, the first electrode 4 is formed easily with uniform thickness, and the decreasing optical transparency of the first electrode 4 is further suppressed. Thus, via the first electrode 4, the sufficient light is incident to the photoelectric conversion element or is emitted from the photoelectric conversion element.

In the case of forming the layer of transparent conductive oxide as the first electrode 4 on the first base material 7, the first electrode 4 can be formed on transparent first base material 7 such like glass and resin by vacuum process such like vapor deposition and sputtering, or the first electrode 4 can be formed as the layer of transparent conductive oxide such like indium oxide, tin oxide and zinc oxide by the wet process such like spin coating method, spray, and screen printing.

The second electrode 6 functions as an anode of the photoelectric conversion element. The second electrode 6 is, for example, formed on the second base material 8 by stacking the conductive material. It is possible to be formed a single film of the metal as the second electrode 6. Although a material for forming the second electrode 6 depends on kinds of the photoelectric conversion element, for example, the material comprises the metal such like platinum, gold, silver, copper, aluminum, rhodium, and indium, carbon material such like graphite, carbon nanotubes and carbons carrying platinum, conductive metal oxide such like indium-tin composite oxide, tin oxide doped with antimony, and tin oxide doped with fluorine, and/or conductive polymeric material such like polyethylene dioxy thiophene, polypyrrole and polyaniline. For forming the second electrode 6 on the second base material 7, it is possible to carry out with the same method as forming the second electrode 4 on the first base material 7.

The second base material 8 can be formed with the same material as the first base material 8. In the case of forming the second electrode 6 on the second base material, it is possible to use the second base material with or without the light-transmissive. In order to enable that light is incident from both sides of the electron-transport layer 1 and the upper side of the hole transport layer 5 or is emitted from both sides of the electron-transport layer 1 and the upper side of the hole transport layer 5, the second base material 8 preferably has the transparency.

The electron transport layer 1 comprises the organic compounds. The molecule of the organic compounds has redox moiety causing repetitive oxidation-reduction reactions, and has the moiety for forming gel (hereafter indicated as gel moiety) with the electrolyte solution. The redox moiety is chemically bonded with the gel moiety. The positional relationship within molecule between the redox moiety and the gel moiety is not especially limited. For example, in the case of forming the gel moiety as the molecular framework such like the main chain of molecule, the redox moiety is formed as the side chain by bonding with the main chain. The molecular framework forming as the gel moiety and the molecular framework forming as the redox moiety can be alternately arranged and bonded. Thus, it is possible to retain the redox moiety within gel layer 2 with keeping the redox moiety at the position for the easy electron transport because the redox moiety and the gel moiety are presence within an identical molecule.

The organic compound having the redox moiety and the gel moiety may be the low molecular compound or may be the polymeric compound. When the organic compound is the low molecular compound, the organic compound can be used for forming a low molecular-gel via hydrogen bond. When the organic compound is the polymeric compound, the organic compound having a number-average molecular weight of at least 1000 is preferably used because the organic compound easily expresses the gelling function. Herein, although the largest value of molecular weight in the polymeric compound is not especially limited, the preferable molecular weight is not more than one million. The gel layer 2 preferably has a visual form such like a konjak or ionic exchange film, but it is not limited in above gelling form.

The redox moiety is indicated as the moiety becoming to oxidant and reductant reversibly in oxidation-reduction reactions. The redox moiety allows to be the moiety forming one pair of redox system comprising the oxidant and the reductant, but is not especially limited in above mentions. For example, it is preferable to have a same charge between the oxidant and the reductant in the redox moiety.

About the gel layer 2, the degree of swelling is exemplified as a physical index indicating the effect by the wide of the reaction interface. Herein, the degree of swelling is indicated as an equation.

The degree of swelling=(the weight of gel)/(the weight of dried gel)×100

The dried gel is obtained by drying the gel layer 2. The drying the gel layer 2 is indicated as removing the solution within gel layer 2, especially removing the solvent. The method of drying gel layer 2 is exemplified as heating, removing the solution or the solvent in a vacuum room, or removing the solution or the solvent within the gel layer 2 by using another solvent.

Additionally, in the case of removing the solvent or solution within gel layer 2 by using another solvent, if the another solvent is selected as the solvent which has a high affinity to the solution and the solvent within gel layer 2 and is removed by heating and vacuum, the solution or the solvent within the gel layer 2 is effectively removed.

The degree of swelling of gel layer 2 is preferably defined in range of 110 to 3000%, and more preferably in range of 150 to 500%. In one hand, when the degree of swelling is less than 110%, it has possibility that the redox moiety is not sufficiently stabilized because of insufficient electrolyte components within the gel layer 2. In other hand, when the degree of swelling is beyond 3000%, it has possible that the electron transportation is decreased because of insufficient redox moiety within the gel layer 2. Therefore, the photoelectric conversion element becomes to have low properties in either case.

The organic compound has the redox moiety and the gel moiety in one molecule, and the organic compound like above is generalized as follows.

(Xᵢ)ₙⱼ:Yₖ

(Xᵢ)ₙ is indicated as the gel moiety, and Xᵢ is indicated as a monomer for forming the gel moiety. The gel moiety can be comprised in a polymer skeleton. The polymerization degree (n) of the monomer is preferably defined as the range of 1 to 100,000. Y is indicated as the redox moiety. Further, Y connects with (Xᵢ)ₙ. Each of j and k is an optional integer to represent as a number of (Xᵢ)ₙ and Y, respectively, both of which are comprised in one molecule. Both j and k are preferably defined in the range in the range of 1 to 100,000. The redox moiety Y and the gel moiety (Xᵢ)ₙ are formed as polymer molecule, and can be present in any position in the polymer skeleton. Additionally, it is possible to comprise different kinds of the redox moiety Y. In this case, the redox moiety preferably has similar redox potential in view of an electron exchange reaction.

The organic compound comprises the redox moiety Y and the gel moiety (Xᵢ)ₙ in one molecule as like above. Such the organic compound is exemplified as a polymer having a quinone derivative's frame comprising quinones via chemical bond, a polymer having an imide derivative's frame, a polymer having a phenoxyl derivative's frame and a polymer having a viologen derivative's frame. In these organic compounds, each of polymer skeleton is functioned as the gel moiety, and each the quinine derivative's frame, the imide derivative's frame, the phenoxyl derivative's frame and the viologen derivative's frame is functioned as the redox moiety.

In above organic compounds, the quinine derivative's frame is, for example, represented as chemical structures [Formula 1] to [Formula 4] as follows. In [Formula 1] to [Formula 4], R is exemplified as saturated or unsaturated hydrocarbons such like methylene, ethylene, propane-1,3-dienyl, ethylidene, propane-2,2-diyl, alkanediyl, benzylidene, propylene, vinylidene, propene-1,3-diyl and but-1-ene-1,4-diyl; cyclic hydrocarbons such like cyclohexane diyl, cyclohexene-diyl, cyclohexadiene diyl, phenylene, naphthalene and biphenylene; keto or bivalent acyl group such like oxalyl, malonyl, succinyl, glutanyl, adipoyl, alkanedioyl, sebacoyl, fumaroyl, maleoyl, phthaloyl, isophthaloyl and terephthaloyl; ether or esters such like oxy, oxymethylenoxy and oxycarbonyl; a group comprising sulfur such like sulfanediyl, sulfanil and sulfonyl; a group comprising nitrogen such like imino, nitrilo, hydrazo, azo, azino, diazoamino, urylene and amide; a group comprising silicon such like silanediyl and disilane-1,2-diyl; or a group substituted or conjugated a terminus of above groups. [Formula 1] is an example of the organic compound obtained by conjugating chemically an anthraquinone to a polymer main chain. [Formula 2] is an example of the organic compound obtained by incorporating anthraquinones as repetitive unit to a polymer main chain. [Formula 3] is an example of the organic compound obtained by forming anthraquinone as cross-linking unit. [Formula 4] represents an example of anthraquinone having a proton donor group for forming the hydrogen bond with oxygen atom in the molecule.

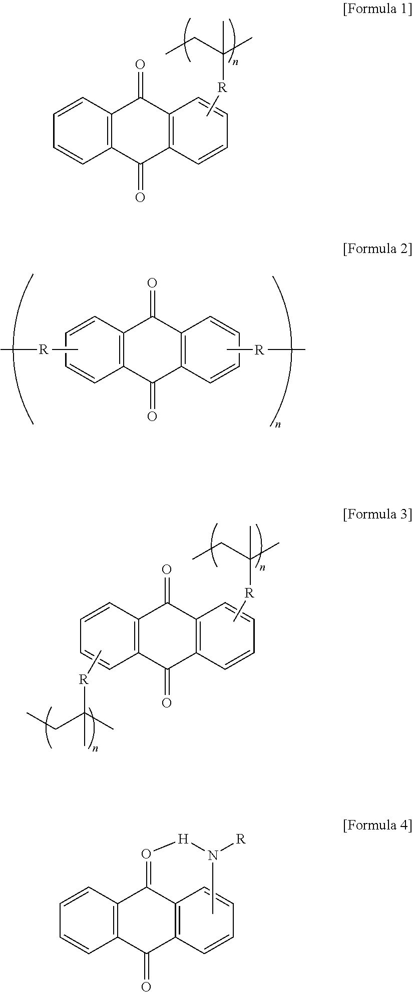

Above quinone polymers enable a high speed redox reactions without accepting a rate limiting by a proton movement. An electric interaction is not present between the quinone groups which are functioned as the redox moiety (redox site). Consequently, the quinone polymers have a chemical stability for a long term use. Moreover, the quinone polymers are useful in that the electron transport layer 1 can be formed with retaining on the first electrode 4 because the quinone polymers do not elute in the electrolyte solution.

The polymer having imide derivative's frame (imide polymer) is exemplified as [Formula 5] and [Formula 6]. In [Formula 5] and [Formula 6], R₁˜R₃ are defined as an aromatic group such like phenylene group, an alkylene group, a fatty group such like alkyl ether or an ether group. Although the imide polymer's frame may be cross linked at the position of R₁ to R₃, the imide polymer may not have the cross linked structure if the imide polymer's frame only swells in the solvent, and if does not elute in the solvent. When the imide polymer is cross linked, the cross linked position is suited to the gel moiety (Xᵢ)ₙ. When the cross linked structure is formed between the imide polymer's frames, an imide group may be comprised in a cross linking unit. As the imide groups, for example, phthalimide and/or pyromellitimide is preferably used because of electrochemically reversible redox property.

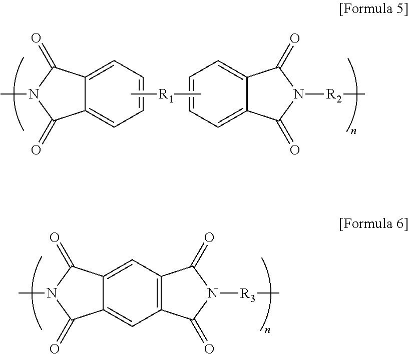

The polymer having phenoxyl derivative's frame is exemplified as galvi polymer (galvi compound) represented in [Formula 7]. In the galvi compound, galvinoxyl group (see. [Formula 8]) is suited to the redox moiety Y, and polymer skeleton is suited to the gel moiety (Xᵢ)ₙ.

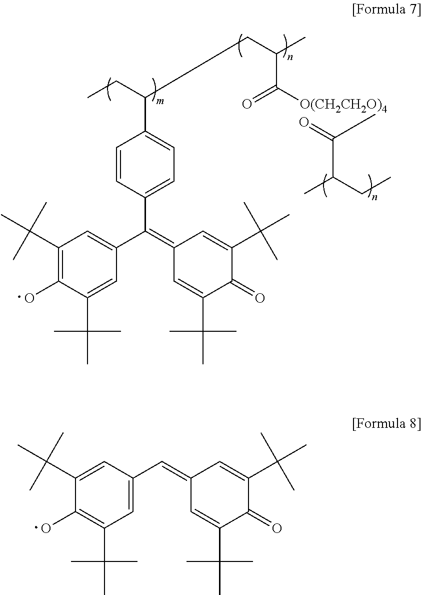

The viologen derivative's frame is exemplified as viologen polymer represented in [Formula 9] and [Formula 10]. In the viologen polymer, a formula represented in [Formula 11] is suited to the redox moiety Y, and polymer skeleton is suited to the gel moiety (Xᵢ)ₙ.

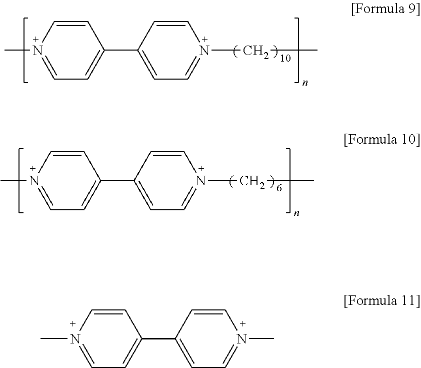

In above [Formula 1] to [Formula 3]; [Formula 5] to [Formula 7]; [Formula 9] and [Formula 10], m and n are indicated as the degree of polymerization. The values of m and n are preferably defined in the range of 1 to 100,000.

Like above mentions, the gel layer 2 is swelled and formed by comprising the electrolyte solution between the polymer skeletons of the organic compound having the gel moiety and the redox moiety. Herein, the gel moiety is comprised in the polymer skeleton. Consequently, the redox moiety is stabilized because a counter ion in the electrolyte solution compensates an ionization state obtained via oxidation-reduction reactions of redox moiety with comprising the electrolyte solution in the electron transport layer 1 formed by using the organic compound.

The electrolyte solution comprises at least an electrolyte and a solvent. The electrolyte means one of a supporting salt and one pair of redox system constituents comprising an oxidant and a reductant, or means both of the supporting salt and the one pair of redox system constituents. The supporting salt (supporting electrolyte) is exemplified as ammonium salt such like tetrabutylammonium perchlorate, tetraethylammonium hexafluorophosphate, imidazolium salt and pyridinium salt; and alkali metal salt such like lithium perchlorate and potassium tetrafluorborate. The redox system constituent means one pair of materials existing as reversible conformation between the oxidant and the reductant in the oxidation-reduction reactions. Herein, the redox system constituent is exemplified as a chlorine compound—chlorine, an iodine compound—iodine, a bromine compound—bromine, a thallium ion (III)—thallium ion (I), a mercurial ion (II)—mercury ion (I), a ruthenium ion (III)—ruthenium ion (II), a copper ion (II)—copper ion (I), an iron ion (III)—iron ion (II), a nickel ion (II)—nickel ion (III), a vanadium ion (III)—vanadium ion (II), a manganate ion—permanganate ion, but is not limited in above. The redox system constituent is distinguished from the redox moiety within the electron transport layer 1, and functions. The electrolyte solution may be gelled or immobilized, such like aforementioned.

A solvent constitutes the electrolyte solution, and comprises at least one of a water, an organic solvent and an ionic liquid.

Because a reduction state is stabilized in the redox moiety of the organic compound by using a water and/or an organic solvent as the solvent of the electrolyte solution, the electrons are transported stably. Although it is possible to use both water and an organic solvent, an organic solvent having excellent ionic conduction is preferably used for more stabilization of the redox moiety. The above organic solvent is exemplified as a carbonate compound such like dimethyl carbonate, diethyl carbonate, methylethyl carbonate, ethylene carbonate and propylene carbonate; an ester compound such like methyl acetate, methyl propionate and γ-butyrolactone; an ether compound such like diethylether, 1,2-dimethoxy ethane, 1,3-dioxosilane, tetrahydrofuran and 2-methyl-tetrahydrofuran; a heterocyclic compound such like 3-methyl-2-oxazolidinone and 2-methylpyrrolidone; a nitrile compound such like acetonitrile, methoxy acetonitrile and propionitrile; and an aprotic polar compound such like sulfolane, dimethylsulfoxide and dimethylformamide. These organic solvents can be used independently, respectively. Furthermore, at least two kinds of these organic solvent can be mixed and used together. Especially, in view of improving an output property for a solar cell by using the photoelectric conversion element, the organic solvent is preferably selected in a carbonate compound such like ethylene carbonate and propylene carbonate; γ-butyrolactone; 3-methyl-2-oxazolidinone; a heterocyclic compound such like 2-methylpyrrolidone; and a nitrile compound such like acetonitrile, methoxy acetonitrile, propionitrile, 3-methoxy propionitrile and valeronitrile.

When an ionic liquid is used as a solvent of the electrolyte solution, it is possible to obtain an excellent stability because of a stabilized redox moiety, a nonvolatile ionic liquid and a high flame resistance. Although all of well-known ionic liquid can be used as the ionic liquid, the ionic liquid is, for example, indicated as an imidazolium type such like 1-ethyl-3-methylimidazolium tetracyanoborate; pyridine type; alicyclic amine type; fatty amine type and azonium amine type. Additionally, the ionic liquid disclosed in the description of European Patent No. 718288; the international publication of WO95/18456; electrochemical (1997) Vol. 65, No. 11, Page 11; J. Electrochem. Soc. (1993) Vol. 143, No. 10, Page 3099; and Inorg. Chem. (1996) Vol. 35, Page 1168 is also exemplified for using.

Like above, the electron transport layer 1 is formed by laying the gel layer 2 on the surface of the electrode 4. Hereby, the gel layer 2 is formed by using the electrolyte solution and the organic compound having the redox moiety. As aforementioned, a formed electron transport layer 1 has a behavior as dopant of an electron. For example, the electron transport layer 1 comprises the redox moiety in which a redox potential is +100 mV higher than a silver-silver chloride reference electrode 4.

A thickness of the electron transport layer 1 is preferably defined in the range of 10 nm to 10 mm, more preferably in the range of 100 nm to 10 μm. Consequently, the electron transport layer 1 becomes to have both excellent electron transport property and wide area of interface at high level by above thickness.

When the electron transport layer 1 is formed on a surface of the electrode 4, it is preferable to form the electron transport layer 1 with applying a solution or the like, because of easier and cheaper formation process. Especially, in the case of forming the electron transport layer 1 by using a polymer material having at least number average molecular weight 1000 as the organic compound, a wet formation process is preferably in view of formability. A wet process is exemplified as a spin coating; a drop casting by drying a dropped liquid; a printing such like screen printing and gravure printing. As the other process, it is possible to carry out with a vacuum process such like sputtering and vapor deposition method.

In order to absorb visible light and near-infrared light efficiently, a sensitizer dye may be contacted with the electron transport layer 1, and may be laid on an interface between the electron transport layer 1 and the hole transport layer 5. The gel layer 2 is formed by swelling the organic compound with the electrolyte solution in the electron transport layer 1, in which the organic compound has the redox moiety. On the other hand, because the hole transport layer 5 comprises similar or same electrolyte solution with above the electrolyte solution, the electrolyte solution comprised within the gel layer 2 also becomes a part of the hole transport layer 5. Therefore, the sensitizer dye is laid on an interface between the electron transport layer 1 and the hole transport layer 5 by presence of the sensitizer dye within the gel layer 2 via adhesion, absorption or bond of the sensitizer dye with a surface of the organic compound forming the electron transport layer 1. A dye sensitized photoelectric conversion element is formed by laying the sensitizer dye as aforementioned.

A well-known material can be used as the sensitizer dye. Herein, the sensitizer dye is exemplified as a 9-phenylxanthene type dye, a coumarin type dye, an acridine type dye, a triphenylmethane type dye, a tetraphenylmethane type dye, a quinone type dye, an azo type dye, an indigo type dye, a cyanine type dye, a merocyanine type dye and a xanthene type dye. Additionally, the sensitizer dye is exemplified as a ruthenium-cis-diaqua-bipyridyl complex in a RuL₂(H₂O)₂ type (herein, L is indicated as 4,4′-dicarboxyl-2,2′-bipyridine); and a transition metal complex such like ruthenium-tris (RuL₃), ruthenium-bis(RuL₂), osmium-tris (OsL₃) and osmium-bis(OsL₂), too. More additionally, the sensitizer dye is exemplified as a sensitizer dye disclosed in the chapter of DSSC in “State of the Art and Material Development of FPD, DSSC, Photo-memory and Functional Dye” can be applied with FPD, DSSC, an optical memory and the state-of-the-art of the functional pigment” (NTS Co. Ltd.), too. Especially, the dye having association is preferably used in view of promoting a charge separation in photoelectric conversion. As the dye having an effect by forming an assembly, the dye is preferably used as a dye represented in [Formula 12].

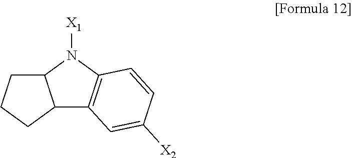

In the above formula, X₁ and X₂ are an organic group having at least one kind in set of alkyl group, alkenyl group, aralkyl group, aryl group and heterocyclic ring, and may have a substituent, respectively. It is known that a dye like [Formula 12] has association. In this case, the photoelectric conversion element is improved the conversion efficiency by dramatic decrease of a recombination of an electron with a hole which are existing in the electron transport layer 1 and the hole transport layer 5.

The sensitizing dye comprised in the electron transport layer 1 exists within the gel layer 2. Especially, the sensitizing dye is preferably immobilized within gel layer 2 via physical or chemical action between the organic compound and the sensitizing dye. Herein, the organic compound is comprised in the gel layer 2. In addition, the sensitizing dye preferably exists throughout in the gel layer 2.

In that the sensitizing dye exists within the gel layer 2, it means that the sensitizing dye exists not only in surface layer of the gel layer 2, but also exists in an internal of the gel layer 2. Consequently, the amount of the sensitizing dye existing within the gel layer 2 is kept as more than definite value continuously, and the photoelectric conversion element is improved in an output effect.

In a state that the sensitizing dye exists within the gel layer 2, both a state that the sensitizing dye exists in the electrolyte solution comprised in the gel layer 2, and a state that the sensitizing dye is retained within the gel layer 2 via physical or chemical interaction between the organic compound comprised in the gel layer 2 and the sensitizing dye are included.

In a state that the sensitizer dye is retained within the gel layer 2 via physical interaction with the organic compound comprised in the gel layer 2, for example, it means that a molecular movement of the sensitizer dye is inhibited within the gel layer 2 by using the organic compound which has an inhibition of movement of a sensitizer dye molecule within the gel layer 2, and by comprising the organic compound in the gel layer 2. A structure for an inhibition of the sensitizer dye molecule is exemplified as the structure expressing a steric exclusion of each molecular chains of the organic compound such like alkyl chain; and as the structure having the small range which a void size between a molecular chains of the organic compound can inhibit a movement of the sensitizer dye molecule.

It is effective to induce a factor for expressing a physical interaction by the sensitizer dye. Specifically, it is effective that a structure is added some molecular chain such like an alkyl chain in order to express a steric exclusion, and that at least two sensitizer dye molecules are connected. In order to connect between the sensitizer dye molecules, it is effective to utilize saturated hydrocarbons such like methylene, ethylene, propane-1,3-dienyl, ethylidene, propane-2,2-diyl, alkane diyl, benzylidene and propylene; unsaturated hydrocarbons such like vinylidene, propene-1,3-diyl and but-1-ene-1,4-diyl; cyclic hydrocarbons such like cyclohexane diyl, cyclohexene diyl, cyclohexadiene diyl, phenylene, naphthalene and biphenylene; a keto such like oxalyl, malonyl, succinyl, gluthanyl, adipoyl, alkanedioyl, sebacoyl, fumaroyl, maleoyl, phthaloyl, isophthaloyl and terephthaloyl; a bivalent acyl group; ethers and/or esters such like oxy, oxymethylenoxy and oxycarbonyl; a group comprising sulfer such like sulfanediyl, sulfanil and sulfonyl; a group comprising nitrogen such like imino, nitrilo, hydrazo, azo, azino, diazoamino, urylene and amide; a group comprising silicon such like silanediyl and disilane-1,2-diyl; or a group substituted or conjugated a terminus of above groups. Above groups are preferably bonded with the sensitizer dye via an alkyl group allowed to become normal chain or branched chain by substitution such like methyl, ethyl, i-propyl, butyl, t-butyl, octyl, 2-ethylhexy, 2-methoxyethyl, benzyl, trifluoromethyl, cyanomethyl, ethoxycarbonylmethyl, propoxy ethyl, 3-(1-octyl pyridinium-4-yl)propyl and 3-(1-butyl-3-methylpyridinium-4-yl)propyl; and/or an alkenyl group allowed to become normal chain or branched chain by substitution such like vinyl and allyl.

In addition, in a state that retains the sensitizer dye within the gel layer 2 by chemical interaction between the organic compounds and the sensitizer dye, for example, it means a state that the sensitizer dye is retained within the gel layer 2 by chemical interaction such like a force based on covalent bond, coordinate bond, ionic bond, hydrogen bond, Van der Waals bond, hydrophobic interaction, hydrophilic interaction or electrostatic interaction between the sensitizer dye and the organic compound. Like above, when the sensitizer dye is immobilized within the gel layer 2 by chemical interaction between the sensitizer dye and the organic compound comprised in the gel layer 2, electrons move effectively because the distance between the sensitizer dye and the organic compound comprised in the gel layer 2 becomes narrower.

When the sensitizer dye is immobilized within the gel layer 2 by chemical interaction between the organic compound and the sensitizer dye, a functional group is accordingly introduced to the organic compound and the sensitizer dye. The sensitizer dye is preferably immobilized to the organic compound by chemical reaction via above functional group. The functional group is exemplified as a hydroxyl group, a carboxyl group, a phosphate group, a sulfo group, a nitro group, an alkyl group, a carbonate group, an aldehyde group and a thiol group. Additionally, a type of chemical reaction via the functional group is exemplified as a condensation reaction, an addition reaction and a ring-opening reaction.

In a chemical bond between the sensitizer dye and the organic compound comprised in the gel layer 2, the functional group of the sensitizer dye is preferably introduced near a site to become higher electron density in an excitation state of the sensitizer dye by light, and the functional group of the organic compound in the gel layer 2 is preferably introduced near a site connecting with an electron transportation of the organic compound. In this case, it is able to improve the efficiency of an electron transport in the organic compound and the efficiency an electron transport from the sensitizer dye to the organic compound. Especially, when the sensitizer dye and the organic compound comprised in the gel layer 2 are bonded each other via a coupling group having high electron transport for connecting an electron cloud of the organic compound with an electron cloud of the sensitizer dye, it is possible to transport an electron effectively from the sensitizer dye to the organic compound. Specifically, it is exemplified that π electron cloud of the sensitizer dye and π electron cloud of the organic compound are connected via a chemical bond by using an ester bond and the like which has π electron.

The timing for connecting the sensitizer dye and the organic compound is accordingly carried out, for example, when the organic compound exists as monomer; when the organic compound is polymerized; when the organic compound is gelled via polymerization of the organic compound; or after the organic compound is gelled. Specific technique is exemplified as a method that the electron transport layer 1 formed by using the organic compound is soaked in a bath comprising the sensitizer dye; a method that the electron transport layer 1 is formed by filling an embrocation comprising the organic compound and the sensitizer dye on the electrode 4. Multiple methods may be combined for connecting the sensitizer dye and the organic compound.

Like above, when the sensitizer dye is immobilized by physical or chemical interaction between the sensitizer dye and the organic compound comprised in the gel layer 2, an electron transport efficiency between the sensitizer dye and the organic compound is improved by becoming narrow between the sensitizer dye and the organic compound.

Although the content of the sensitizer dye within the gel layer 2 can be accordingly set, if the content of the sensitizer dye is defined as at least 0.1 weight parts to 100 weight parts of the organic compound, the amount of the sensitizer dye is sufficient increased in unit thickness of the gel later 2. Consequently, high current value is obtained because photo-absorption ability is improved in the sensitizer dye. And if the content of the sensitizer dye is defined as not more than 1000 weight parts to 100 weight parts of the organic compound, high conductive effect is obtained because it is suppressed that the sensitizer dye interjacents in excess amount between the organic compounds, and that the electron transport within the organic compound is prevented by the sensitizer dye.

In this embodiment, the conductive agent 3 exists within the gel layer 2. The conductive agent 3 is used for improving the electron transport property between the electron transport layer 1 and the first electrode 4. For example, preferably, multiple conductive agents 3 are mixed and are connected with contact each other within the electron transport layer 1, and a part of the conductive agents 3 preferably have a state contact with the electrode 4. In this case, because electrons move via the conductive agent 3 from the electron transport layer 1 to the first electrode 4 or from the first electrode 4 to the electron transport layer 1, the electrons is transported very rapidly. Thus, the electron transport property between the electron transport layer 1 and the electrode 4 is further improved. In the case of a dye sensitized photoelectric conversion element and the like, because the conductive agent 3 efficiently collects electrons from the electron transport layer 1, it is possible to transport the electrons to the first electrode 4 rapidly.

The conductive agent 3 existing within the gel layer 2 of the electron transport layer 1 preferably comprises a material having both translucency and conduction. Specifically, a conductive material is preferably existed within the electron transport layer 1. The conductive material is preferably indium-tin oxide (ITO), tin oxide, zinc oxide, silver, gold, copper, carbon nanotube, graphite or the like. Additionally, the conductive material is exemplified as Passtran (Trademark) produced by MITSUI MINING & SMELTING CO., LTD which is coated by doping with tin oxide, ITO on a core material consisting of barium sulfate or aluminium borate. More additionally, metal fine particle also can be used as the conductive material by using such that the electron transport layer 1 does not lose translucency.

A volume resistivity of the conductive agent 3 is preferably defined as not more than 10⁷Ω/cm, more preferably a not more than 10⁵Ω/cm, especially preferably as 10Ω/cm. although a lowest value of the volume resistivity is not especially limited, the lowest value is generally approximately 10⁻⁹Ω/cm. Although the resistivity of the conductive agent 3 is not especially mentioned, the conductive agent 3 preferably has an equivalent resistivity with the first electrode 4.

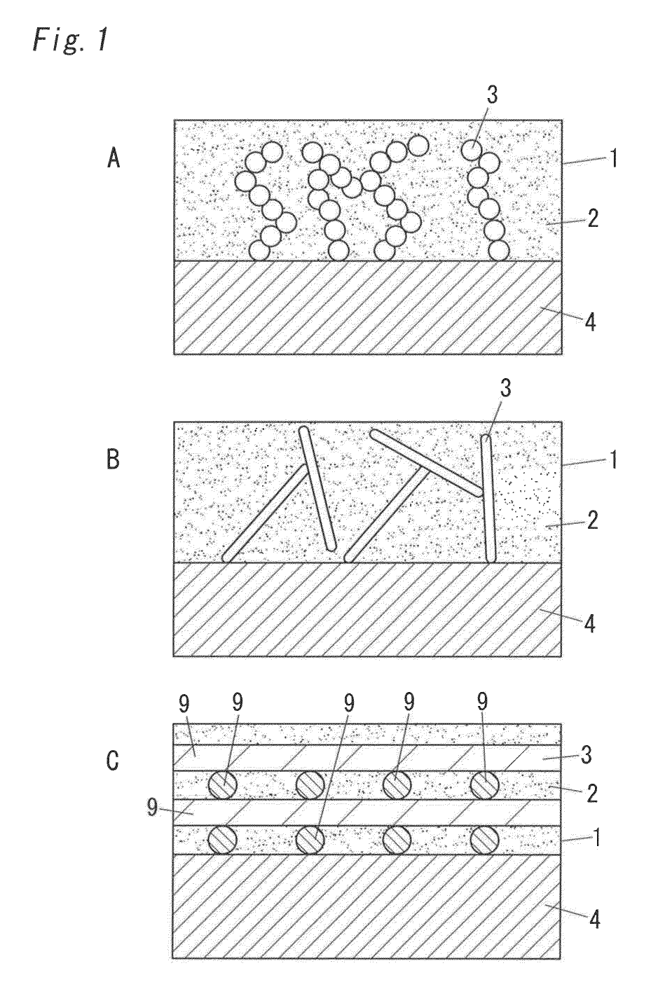

As shown in FIG. 1A, the conductive agent 3 may comprises a coupled mass by connection with contact of multiple conductive particles, or may comprise a conductive sticks as shown in FIG. 1B. When the conductive agent 3 comprises the coupled mass of the conductive particles, that conductive material preferably has an average particle diameter in the range of 1 nm to 1 μm. The average particle diameter is an average value of a particle diameter of the conductive material by measurement via an electron microscope such like SEM. Herein, 30 conductive particles were used for that measurement.

In this case, the conductive material is hard to isolate within the electron transport layer 1 by the average particle diameter of at least 1 nm, and a contact area between the conductive material and the electron transport layer 1 is sufficiently assured by the average particle diameter of not more than 1 μm. Consequently, the conductive agent 3 can bring out a sufficient collecting effect.

The conductive agent 3 preferably has a shape of stick, form the view of increasing a contact area with the electron transport layer 1 and assuring a contact point between the conductive materials. Herein, the stick includes not only straight shape but also a shape such like fiber, needle or a curved and spindly shape. When the conductive agent 3 comprises a conductive stick, an average axial ratio of a long axis and a short axis is preferably defined in the range of 5 to 50. In the case of at least 5 in the average axial ratio, because conductive materials and the conductive material and the first electrode 4 contact each other by mixing within the electron transport layer 1, an electric conductivity is greatly improved. Thus, a resistance decreases in an interface between the electron transport layer 1 and the first electrode 4. Additionally, in the case of not more than 50 in the average axial ratio, the conductive agent 3 is hard to be destroyed mechanically in producing a paste by mixing the conductive agent 3, the organic compound and the like uniformly.

When the conductive agent 3 comprises the conductive sticks, an average outside diameter of a short axis of the conductive material is preferably defined in the range of 1 nm to 20 μm. When the average outside diameter is at least 1 nm in the short axis of the conductive material, the conductive material is hard to be destroyed mechanically at producing a paste by mixing the conductive material and the organic compound uniformly. Consequently, when the electron transport layer 1 is formed by using above paste, it is possible to decrease a resistance in the interface between the electron transport layer 1 and the first electrode 4. Moreover, when the average outside diameter is not more than 20 μm in the short axis of the conductive material, a decreasing of the organic compound is suppressed in a unit volume of the electron transport layer 1 with addition of the conductive material.

The conductive agent 3 especially preferably comprises a conductive fibers. In this case, the conductive fibers are formed as a stack of a state arranged in a surface direction of the first electrode 4. Specifically, a stack structure of the fibers is formed by being arranged the fibers in the surface direction of the first electrode 4 and being stacked the arranged fibers in a thickness direction of the first electrode 4. Consequently, it is possible to obtain a high collecting effect by the conductive agent 3. Additionally, when the conductive material is formed as a fiber, strength of the conductive agent 3 becomes stronger by comprising this conductive material in the conductive agent 3. Therefore, because it is able to increase a void rate of the conductive agent 3 easily, the electron transport layer 1 and/or the gel layer 2 can be easily formed in the void of the conductive agent 3.

When the conductive agent 3 comprises the conductive fibers, an average outside diameter is preferably defined in the range of 50 nm to 1000 nm in a short axis of the conductive fibers. In the case of at least 50 nm in the average outside diameter, because the strength of the conductive agent 3 is further improved, it is able to form the conductive agent 3 having high void rate. Additionally, when the conductive agent 3 is laid on the first electrode 4, only porous conductive film comprising the conductive fibers and having high strength is formed on the first electrode 4. Herein, this porous conductive film is used as the conductive agent 3. Thus, the electron transport layer 1 and/or gel layer 2 can be easily formed in the void of the conductive agent 3. On the other hand, in the case of 1000 nm in the average outside diameter, because the void rate of the conductive agent 3 comprising the conductive fibers is increased and its specific surface area becomes sufficiently large, it is possible that an output of the photoelectric conversion element is improved.

A void rate of the conductive agent 3 comprising the conductive fibers is preferably defined in the range of 50% to 95%. The void rate of the conductive agent 3 comprising the conductive fibers means a void rate of a layer of only the conductive agent 3 (the porous conductive film) excepted the organic compound, the electrolyte solution, and the like from the gel layer 2. When the void rate is defined as at least 50%, it is possible to assure sufficiently a region to enable the photoelectric conversion in the gel layer 2 because the organic compound and the electrolyte solution can be existed in sufficient amount for comprising the electron transport layer 1 and the gel layer 2 within the porous conductive film. On the other hand, when the void rate is defined as not more than 95%, a decreasing effect of a resistance loss is improved because it is suppressed that a distance from the first electrode 4 to the conductive fibers becomes long.

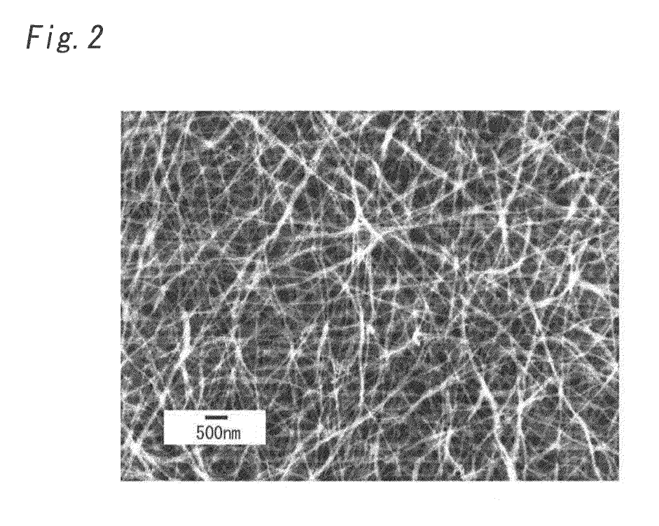

Furthermore, an average fiber length to an average fiber diameter ratio (an average axial ratio) of the conductive fibers is preferably defined as at least 1000. In this case, the conductive fibers are easily stacked in a state arranged in a surface direction of the first electrode 4. As shown in FIG. 1C, it is simply represented that the conductive fibers 9 are comprised in the conductive agent 3 by stacking in the state arranged in a surface direction. In FIG. 2, an electron micrograph is represented in a plan view of the conductive agent 3 comprising the conductive fibers 9. Thus, it is possible to obtain a higher photoelectric conductive efficiency because the void rate becomes higher in the conductive agent 3 comprising the conductive fibers 9.

A roughness factor of the conductive agent 3 in the gel layer 2 is preferably in the range of 5 to 2000. In the case of less than 5 in the roughness factor, it has a possibility that the collecting effect cannot be sufficiently obtained by becoming longer in a distance of the electron transport within the gel layer 2. On the other hand, in the case of larger than 2000 in the roughness factor of the conductive agent 3, it has a possibility that an decreasing of the conductive efficiency is carried out by becoming easy accrual of a side reaction on a surface of the conductive agent 3. By the way, when the first electrode 4 is a transparent film electrode consisting of ITO and the like, the roughness factor becomes to not more than 1.5 because the first electrode 4 is formed as a dense layer without looseness.

Like above, in order to exist the conductive agent 3 within the gel layer 3, a paste mixture is, for example, prepared by mixing the conductive agent 3 and the organic compound to form the electron transport layer 1, then this mixture is formed as a coating film in a similar process with aforementioned forming the electron transport layer 1 on the surface of the first electrode 4. A solution dispersing the conductive material previously is coated on a surface of the first electrode 4, and the conductive agent 3 consisting of the porous conductive film is formed on the first electrode 4 by drying this solution, then a solution comprising the organic compound for the electron transport layer 1 may be coated on this porous conductive film. In this case, the conductive material may be additionally mixed with above solution comprising the organic compound.

As above mixing method of the conductive material and the organic compound for the electron transport layer 1, well-known mixing means such like wheel mounted type kneading machine, ball form kneading machine, blade form kneading machine, roll form kneading machine, mortar, attendance machine, colloidal mill, omni mixer, swinging mixture and electromagnetic mixer can be used. Herewith, a mixture paste or slurry of the organic compound and the conductive material can be obtained.

A material for forming the hole transport layer 5 is exemplified as an electrolyte solution dissolving an electrolyte such like redox pair in a solvent; a solid electrolyte such like molten salt; a p-type semiconductor such like copper iodide; an amine derivative such like triphenyl amine; and an conductive polymer such like polyacetylene, polyaniline and polythiophene.

When the hole transport layer 5 is formed with the electrolyte solution, the hole transport layer 5 can be formed by using the electrolyte solution comprised in the gel layer 2. In this case, one part of the hole transport layer 5 comprises the electrolyte solution comprised in the gel layer 2.

The electrolyte solution may be retained by a polymer matrix. A poly (vinylidene fluoride) type polymer compound used as the polymer matrix is exemplified as a homopolymer of a vinylidene fluoride, or a copolymer of the vinylidene fluoride and other polymerizable monomers (preferably, radical polymerizable monomers). The copolymer consisting of the vinylidene fluoride and other polymerizable monomers (hereafter, polymerizable monomers) is specifically exemplified as hexafluoropropylene, tetrafluoroethylene, trifluoroethylene, ethylene, propylene, acrylonitrile, vinylidene chloride, methyl acrylate, ethyl acrylate, methyl methacrylate and styrene.

The hole transport layer 5 can comprise a stable radical compound. In this case, when it is formed as the photoelectric conversion element, holes generated by a charge separation are effectively transported from the hole transport layer 5 to the second electrode 6 at a reaction interface by a greatly rapid electron transport reaction of the stable radical. Herewith, a photoelectric conversion efficiency of the photoelectric conversion element can be improved.

The stable radical compound is not especially limited if the stable radical compound is chemical species having an unpaired electron, more specifically, chemical compounds having a radical, but the radical compound preferably has a nitroxide (NO.) in the molecule. A molecular weight (number average molecular weight) is preferably defined as at least 1000 in the stable radical compound. If the molecular weight is at least 1000, it is preferably from the view of stability of the element because the stable radical compound becomes a solid or a like solid in a room temperature and is hard to be evaporated.

This stable radical compound is further explained. The stable radical compound is a chemical compound to generate as a radical compound in at least one process of an electrochemical oxidation reaction or an electrochemical reduction reaction. Although species of the radical compound is not especial limited, it is preferably that the radical compound is stable. Especially, it is preferably that the radical compound is an organic compound comprising one hand of or both of structural units represented as [Formula 13] and [Formula 14].

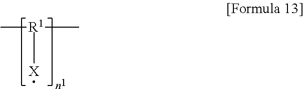

In above [Formula 13], a substituent R¹ is indicated as an alkylene group having C2 to C30, an alkenylene group having C2 to C30, or an arylene group having C4 to C30 in substituted or unsubstituted. Additionally, X is indicated as an oxy radical group, a nitroxyl radical group, a sulfur radical group, a hydrazyl radical group, a carbon radical group or boron radical group. More additionally, n¹ means an integral number of at least 2.

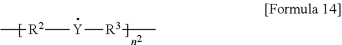

In above [Formula 14], substituents R¹ and R² isolating each other are indicated as an alkylene group having C2 to C30, an alkenylene group having C2 to C30, or an arylene group having C4 to C30 in substituted or unsubstituted. Additionally, Y is indicated as a nitroxyl radical group, a sulfur radical group, a hydrazyl radical group, a carbon radical group or boron radical group. More additionally, n² means an integral number of at least 2.

The stable radical compound comprising at least one hand of the structural units represented as [Formula 13] and [Formula 14] is exemplified as an oxy radical compound, a nitroxyl radical compound, a carbon radical compound, a nitrogen radical compound, a boron radical compound and a sulfur radical compound. A number average molecular weight is preferably defined in the range of 10³ to 10⁷, more preferably in the range of 10³ to 10⁵ in the organic compound to generate this radical compound.

The oxy radical compound is specifically exemplified as an aryl oxy radical compound represented in [Formula 15] and [Formula 16], and a semiquinone radical compound represented in [Formula 17].

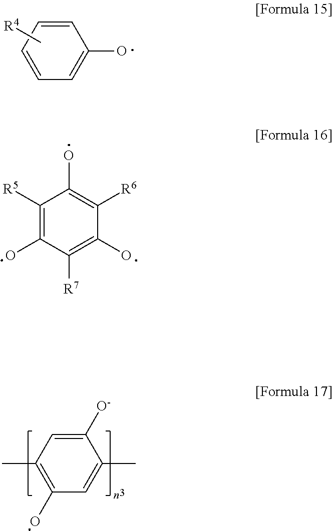

In [Formula 15] to [Formula 17], substituents R⁴ to R⁷ isolating each other are indicated as a hydrogen atom, a fatty or an aromatic hydrocarbon group having C1 to C30 in substituted or unsubstituted, a halogen group, a hydroxyl group, a nitro group, a nitroso group, a cyano group, an alkoxy group, an aryloxy group, or an acyl group. In [Formula 17], n³ means an integral number of at least 2. Herein, a number average molecular weight is preferably defined in the range of 10³ to 10⁷ in the organic compound to generate the radical compound represented in any of [Formula 15] to [Formula 17].

The nitroxyl radical compound is specifically exemplified as a radical compound having a piperidinoxy cyclic ring represented in [Formula 18], a radical compound having a pirrolidinoxy cyclic ring represented in [Formula 19], a radical compound having a pirrolinokyne cyclic ring represented in [Formula 20], and a radical compound having a nitronyl nitroxide structure represented in [Formula 21].

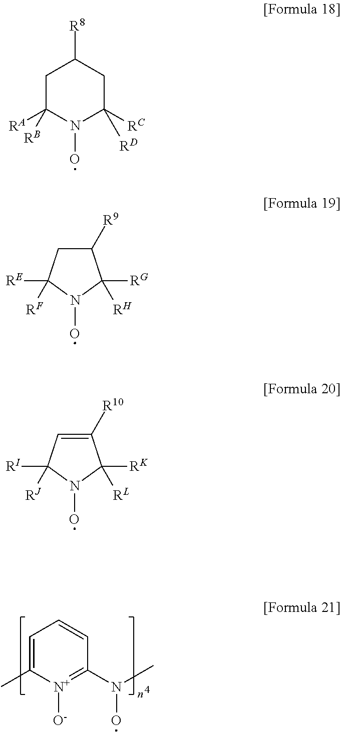

In [Formula 18] to [Formula 20], R⁸ to R¹⁰ and R^{A} to R^{L} which isolate each other are indicated as a hydrogen atom, a fatty or aromatic hydrocarbon group having C1 to C30 in substituted or unsubstituted, a halogen group, a hydroxyl group, a nitro group, a nitroso group, a cyano group, an alkoxy group, an aryloxy group, or an acyl group. In [Formula 21], n⁴ means an integral number of at least 2. Herein, a number average molecular weight is preferably defined in the range of 10³ to 10⁷ in the organic compound to generate the radical compound represented in any of [Formula 18] to [Formula 21].

The nitro radical compound is specifically exemplified as a radical compound having a trivalent hydrazyl group represented in [Formula 22], a radical compound having a trivalent verdazyl group represented in [Formula 23], and a radical compound having an aminotriazine structure represented in [Formula 24].

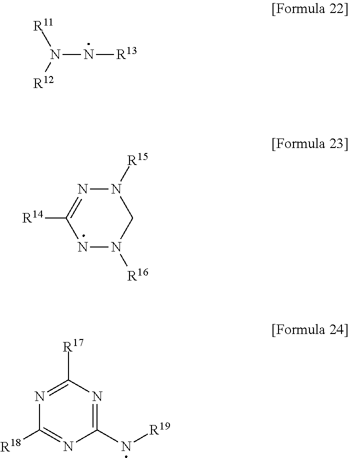

In [Formula 22] to [Formula 24], R¹¹ to R¹⁹ which is olate each other are indicated as a hydrogen atom, a fatty or an aromatic hydrocarbon group having C1 to C30 in substituted or unsubstituted, a halogen group, a hydroxyl group, a nitro group, a nitroso group, a cyano group, an alkoxy group, an aryloxy group, or an acyl group. Herein, a number average molecular weight is preferably defined in the range of 10³ to 10⁷ in the organic compound to generate the radical compound represented in any of [Formula 22] to [Formula 24].

The number average molecular weight is especially preferably defined in the range of 10³ to 10⁷ in the radical compound represented in any of [Formula 13] to [Formula 24]. The organic compound has an excellent stability by having the number average molecular weight in this range. As a result, the photoelectric conversion element can be stably used as an energy accumulation element and a photoelectric element. Additionally, it is possible to obtain easily the photoelectric conversion element with an excellent stability and an excellent speed of response.

The stable radical compound is preferably selected as the organic compound with a solid state at room temperature in above organic compound. In this case, because a contact of the radical compound and the electron transport layer 1 is kept stably, it is possible to suppress a side reaction and a melting with other chemical material, a transmutation by diffusion, and degradation. As a result, it is able to obtain the photoelectric conversion element having an excellent stability.

When the photoelectric conversion element is produced, for example, the electron transport layer 1 is immobilized and formed on the first electrode 4 by stacking the organic compound, by a wetting process, on the first electrode 4 laid on the first base material 7. On this electron transport layer 1, the hole transport layer 5 and the second electrode 6 are stacked. In forming the hole transport layer 5 by using the electrolyte solution, for example, a sealant seals between the electron transport layer 1 and the second electrode 6. Then, the hole transport layer 5 can be formed by packing the electrolyte solution in the gap between above electron transport layer 1 and second electrode 6. Herein, the gel layer 2 can be formed by swelling the organic compound comprised in the electron transport layer 1 via infiltrating a part of the electrolyte solution in the electron transport layer 1.

Like above photoelectric conversion element has a sufficient reaction interface by forming the gel layer 2 with the organic compound and the electrolyte solution of the electron transport layer 1. Additionally, the electron transport property is improved by the conductive agent 3 within the gel layer 2. Therefore, photoelectric conversion efficiency is improved in the photoelectric conversion element.

For example, like the case that the photoelectric conversion element is conFig.d as the dye sensitized photoelectric conversion element, in the case that the photoelectric element has a function as the photoelectric conversion element, the sensitizer dye is excited by absorption of light via irradiation of light through the first electrode 4 from the first base material 7 side. A generated electron in an excited state goes into the electron transport layer 1. As a result, the electron is taken out via the first electrode 4, and the hole in the sensitizer dye is taken out from the second electrode 6 from the hole transport layer 5.

In this case, the reaction interface has sufficient area by forming the gel layer 3 with the organic compound and the electrolyte solution of the electron transport layer 1, and the electron generated within the electron transport layer 1 moves rapidly to the electrode 4 via the conductive agent 3 by existing the conductive agent within the gel layer 2. Consequently, because a recombination is suppressed between the electron and the hole, the electron transport property is improved in the electron transport layer 1, and the photoelectric conversion efficiency is improved in the photoelectric conversion element. Especially, when the electron transport layer 1 has a large thickness, the suppressing of the recombination is effectively expressed by existing of the conductive agent 3. Thus, a current value is increased with increasing of a light absorption amount, and the conversion efficiency is improved in the photoelectric conversion element.

### EXAMPLES

The present invention is described in detail by the examples.

Examples in below, a surface area of the conductive material was measured as an actual surface area of the conductive agent 3 by nitrogen absorption method, and a project area of the porous conductive film comprising this conductive material was as the project area of the conductive agent 3. Herewith, the roughness factor of the conductive agent 3 was calculated according to “Roughness Factor=(actual surface area/project area)×100”.

A void volume in the porous conductive film was measured by the pore size distribution measurement method, the void rate is calculated according to “Void rate=(void volume/apparent volume of the porous conductive film)×100”.

### Example 1

### Synthesis of Galvi Monomer

4-bromo-2,6-di-tert-butylphenol (135.8 g; 0.476 mol) and acetonitrile (270 ml) were put into the reaction vessel. Additionally, in the atmosphere of an inert gases, N,O-bis(trimethylsilyl)acetamide (BSA) (106.3 g; 129.6 ml) was added. By stirring at 70° C. over night, the reaction was carried out until crystals separated out completely. The white crystals were filtrated, and dried with vacuum. And then, a white plate-shape crystals of (4-bromo-2,6-di-tert-butylphenoxy)trimethylsilane (150.0 g; 0.420 mol) which is signed as “1” in [Formula 25] are obtained by purifying with recrystallization in ethanol.

In next, (4-bromo-2,6-di-tert-butylphenoxy)trimethylsilane (9.83 g; 0.0275 mol) was dissolved, in the atmosphere of an inert gases, with tetrahydrofuran (200 ml) in the reaction vessel. The prepared solution was cooled at −78° C. by using dry ice and methanol. 1.58M n-butyllithium hexane solution (15.8 ml; 0.025 mol) was added into above solution within the reaction vessel. The lithiation reaction was carried out by stirring at 78° C. for 30 minutes. Then, the tetrahydrofuran solution (75 ml) containing methyl 4-bromobenzoate (1.08 g; 0.005 mol, Mw; 215.0, TCI) was added into above solution, and stirred at −78° C. to the room temperature, over night. Herewith, the color of this solution was changed form yellow to pale yellow, further more changed to dark blue indicating the occurrence of anion. After the reaction, saturated ammonium chloride solution was added into the solution within the reaction vessel until the solution changed to yellow. Then, the product was obtained as a yellow viscous liquid by the extraction form above solution with ether and water.

In next, above product, THF (10 ml), methanol (7.5 ml) and stirrer were put into the reaction vessel. After dissolving, 10N-HCl (1 to 2 ml) was added by bits until color of the solution in the reaction vessel changed to tangerine, and stirred at room temperature for 30 minutes. Then, (p-bromophenyl)hydrogalvinoxyl (2.86 g; 0.0049 mol) which is signed as “2” in [Formula 25] was obtained as orange color crystals by the purification via each steps of the removing of solvent, the extraction with ether and water, the removing of solvent, the fraction by column chromatography (hexane:chloroform=1:1), and the recrystallization with hexane.

After that, the (p-bromophenyl)hydrogalvinoxyl (2.50 g; 4.33 mmol) was dissolved in the atmosphere of an inert gases with toluene (21.6 ml; 0.2 M). 2,6-di-tert-buthyl-p-cresol (4.76 mg; 0.0216 mmol), tetrakis(triphenylphosphine)palladium(0) (0.150 g; 0.130 mmol), and tri-n-butyl(vinyl)tin (1.65 g; 5.20 mmol, Mw: 317.1, TCI) were rapidly added into above solution, and stirred at 100° C. for 17 hours.

Like above, the obtained reaction product was extracted with ether and water, removed the solvent, fractionated by flash column chromatography (hexane:chloroform=1:3) and recrystallized with hexane. p-hydrogalvinoxyl styrene (1.54 g; 2.93 mmol) which is signed as “3” in [Formula 25] was obtained as the orange color microcrystal by purification via above steps.

(Polymerization of Galvimonomer)

In above process, the obtained galvimonomer (p-hydrogalvinoxyl styrene) of 1 g; etraethylene glycol diacrylate of 57.7 mg; and azobisisobutyronitrile of 15.1 mg; were dissolved with 2 ml of tetrahydrofuran. Then, the galvimonomer was polymerized by purging with the nitrogen and by refluxing over night, and the galvipolymer signed as “4” in [Formula 25] was obtained.

(Formation of the Electron Transport Layer and the Conductive Agent)

As the first base material 7 comprising the first electrode 4, a conductive glass base plate having 0.7 mm of the thickness and 100Ω/□ of the sheet resistance was used. This conductive glass base plate comprises a glass base plate, a coated film consisting of SnO₂ by doping with fluorine, and the coated film stacked on a surface of this glass. Herein, the glass base plate is the first base material 7, and coated film is the first electrode 4. By the way, the roughness factor was 1.5 in the coated film.

Above galvipolymer (singed as “4” in [Formula 25]) of 2 weight %; and ITO particles (20 nmφ) of 1 weight % were dispersed and dissolved in chlorobenzene. The conductive agent 3, which consists of the coupled mass of ITO particles, and the electron transport layer 1 are formed at a same time by spin-coating above solution at 1000 rpm on the electrode 2 of the conductive glass base plate and by drying at 60° C. for 1 hour under 0.01 Mpa. The thickness of this conductive agent 3 and electron transport layer 1 was measured as 120 nm. By the way, the roughness factor of the conductive agent 3 was 100, and the void rate of the conductive agent 3 was 40%.

This electron transport layer 1 is soaked in the saturated acetonitrile solution containing a sensitizer dye (D131) represented in [Formula 26] for 1 hour.

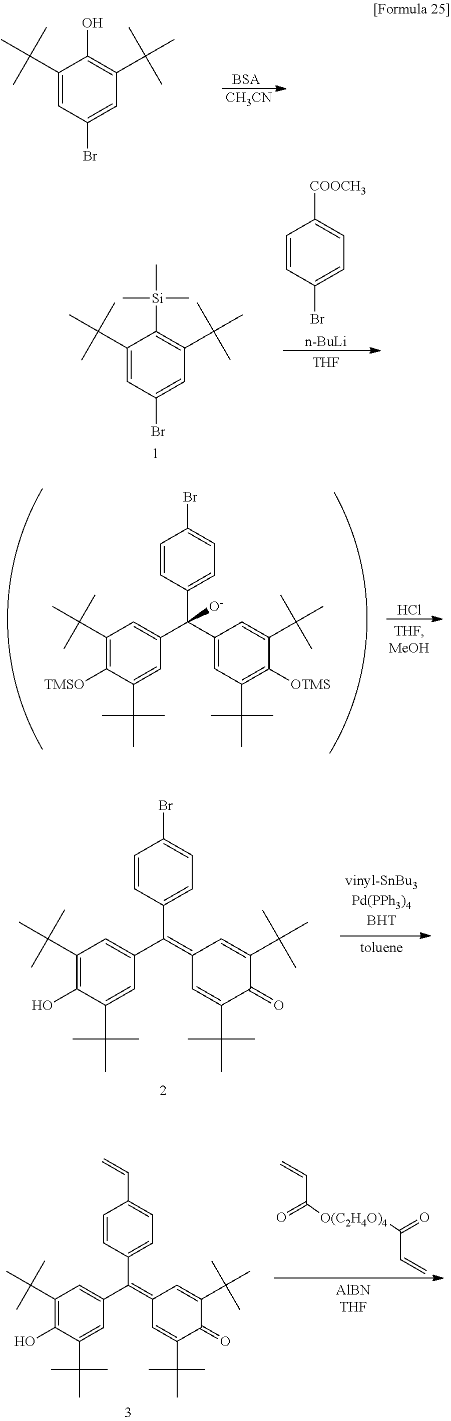

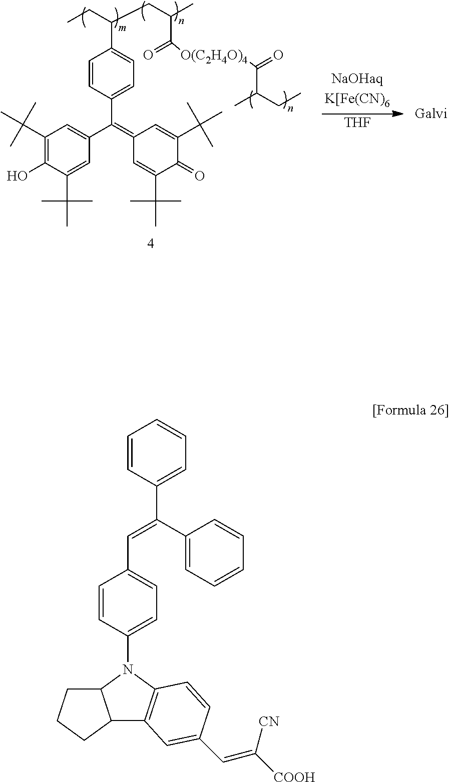

(Production of an Element)

A conductive glass base plate had a similar structure with the conductive glass base plate in the formation of above electron transport layer 1, and was used.

Chloroplatinic acid is dissolved in the isopropyl alcohol as final concentration 5 mM. The obtained solution was coated on the coated film of above conductive glass base plate by spin-coating. Then, the second electrode 6 was formed by baking at 400° C. for 30 minutes.

Next, the conductive glass base plate laid the electron transport layer 1, and the conductive glass base plate laid the second electrode 6 were arranged like that the electron transport layer 1 and the second electrode 6 opposed, and at outer edge between the electron transport layer 1 and the second electrode 6, Bynel (Trade Mark) produced by E. I. du Pont de Nemours and Company was intervened on 1 mm of width and 50 μm of thickness as a hot-melt adhesive agent. Two conductive glass base plates were conjugated via this hot-melt adhesive agent by pressing above two conductive glass base plates in the thickness direction with heating the hot-melt adhesive agent. At a part of laid the hot-melt adhesive agent, a gap was formed as an inlet of the electrolyte solution. Continuously, the electrolyte solution was packed between the electron transport layer 1 and the second electrode 4 via above inlet. A UV indurative resin was coated on the inlet. Then, the inlet was closed by curing above UV indurative resin with irradiation of UV light. Herewith, the hole transport layer 5 consisting of the electrolyte solution was formed, and the gel layer 2 was formed by swelling the organic compound (galvi polymer) with infiltrating above electrolyte solution to the electron transport layer 1. A above electrolyte solution, an acetonitrile solution containing 1 M of 2,2,6,6-tetramethylpiperidinooxy, 2 mM the sensitizer dye (D131); 0.5 M LiTFSI; and 1.6 M N-methylbenzimidazole was used. In above mentioned, the photoelectric conversion element was prepared.

### Example 2

In Example 1, when the conductive agent 3 and the electron transport layer 1 was formed, as a substitute for ITO particles, Passtran (Trade Mark) TYPE-V (average axile rate; 8.0, average short axis diameter; 1 μm) produced MITSUI MINING & SMELTING CO., LTD was used as the conductive sticks (fibers), the conductive sticks (fibers) were dispersed in the solvent, and the prepared liquid contained about 5 weight % of the conductive sticks (fibers). The photoelectric conversion element was produced in the same method as in. Example 1 except above indication. The roughness factor was 150 in the conductive agent 3 comprising the conductive sticks (fibers), and the void rate was 60% in the conductive agent 3 comprising the conductive sticks (fibers).

### Example 3

In forming the electron transport layer 1, tin oxide (average particle diameter; 20 nmφ) was dispersed as final concentration 20 weight % in a terpineol solution containing 20 weight % of ethyl cellulose, and the tin oxide paste was prepared. This tin oxide paste was coated on the conductive glass base plate having the same construction as Example 1. Then, the porous conductive film having 3 μm of thickness was prepared as the conductive agent 3 by baking at 450° C. for 30 minutes. The roughness factor of this conductive agent 3 was 500, and the void rate of this conductive agent 3 was 40%.

Next, a chlorobenzene solution was prepared by dissolving the galvipolymer (signed as “4” in [Formula 25]) in Example 1 at a concentration of 2 weight %. The electron transport layer 1 was formed by drying at 60° C. for 1 hour under 0.01 M Pa after spin-coating above solution at 500 rpm on the porous conductive film. This electron transport layer 1 was soaked in the saturated acetonitrile solution containing the sensitizer dye (D131) represented in [Formula 26] for 1 hour.

The photoelectric conversion element was produced in the same method as in Example 1 except above indication.

### Example 4

In forming the conductive agent 3, in the same method as in the case of Example 3, the conductive agent 3 was prepared as porous conductive film with 10 μm thickness. The roughness factor of this conductive agent 3 was 2000, and the void rate of this conductive agent 3 was 40%.

Next, a chlorobenzene solution was prepared by dissolving the galvipolymer (signed as “4” in [Formula 25]) in Example 1 as the concentration of 2 weight %, and was used. Then, the electron transport layer 1 was prepared in the same method as in Example 3.

The photoelectric conversion element was produced in the same method as in Example 3 except above indication.

### Example 5

In forming the electron transport layer 1, a dimethylformamide solution was prepared. The solution contained polyvinyl acetate (molecular weight; 500,000) as the concentration 14 weight %. Herein, the solution was named as Liquid A. On the other hand, the tin oxide hydrate of 13.5 g was dissolved in ethanol of 100 ml, and the tin oxide sol was prepared by refluxing for 3 hours. Herein, the sol was named as Liquid B. Then, Liquid A and Liquid B were mixed on Liquid A:Liquid B=0.8:1 as weight ratio, and the mixture was stirred for 6 hours. The obtained liquid was named as Liquid C. The liquid C was coated on the transparent electrode of the conductive glass base plate by electro-spinning. Herewith, the porous conductive film having the thickness of 1 μm was prepared as the conductive agent 3. In Above, the porous conductive film comprised the conductive fibers having an average outside diameter (short axis diameter) of 100 nm. An electron micrograph of the porous conductive film is shown in FIG. 2 as planar view. The roughness factor of this conductive agent 3 was 2000, and the void rate of this conductive agent 3 was 80%.

Next, a chlorobenzene solution was prepared by dissolving the galvipolymer (signed as “4” in [Formula 25]) in Example 1 as the concentration of 2 weight %. The electron transport layer 1 was formed by drying at 60° C. for 1 hour under 0.01 MPa after coating above solution on the porous conductive film with spin-coating at 500 rpm.

This electron transport layer 1 is soaked in the saturated acetonitrile solution containing a sensitizer dye (D131) represented in [Formula 26] for 1 hour.

The photoelectric conversion element was produced in the same method as in Example 1 except above indication.

### Comparative Example 1

The photoelectric conversion element was produced in the same method as in Example 1, except without ITO particles. In addition, the roughness factor was 1.5 in the first electrode 4 comprising the coated film. The roughness factor was obtained the same value as in Example 1.

[Evaluation Test]

The planar view area of 1 cm² was irradiated with light of 200 luxes in the photoelectric conversion element obtained in each Examples and Comparative examples, and a open-circuit voltage and a short circuit current value in each photoelectric conversion elements were measured with I-V measurement by using Keithley 2400 source meter produced by Keithley Instruments Inc. As a light source, Rapid (Trade Mark) fluorescent lamp FLR20S W/M produced by Panasonic corporation was used, and measurement was carried out under the atmosphere of 25° C. Additionally, In the condition for photo acception in area of 1 cm² of a photoelectric conversion unit, the evaluation test was carried out for the photoelectric conversion element. Those results were summarized in Table 1.

TABLE 1

| | | | | | | | Short |
|---|---|---|---|---|---|---|---|
| | Conductive agent | | | | | | Circuit |
| | | Formation | | Roughness | Void | Open-Circuit | Current |
| | Species | Method | Thickness | Factor | Rate | Voltage | Value |
| Exam. 1 | Coupled | Forming | 120 nm | 110 | 40% | 530 mV | 2.5 μA/cm² |
| | Mass | with an | | | | | |
| | of | electron | | | | | |
| | ITO | transport | | | | | |
| | Particles | layer | | | | | |
| Exam. 2 | Conductive | Forming | 120 nm | 150 | 60% | 540 mV | 2.0 μA/cm² |
| | Sticks | with an | | | | | |
| | | Electron | | | | | |
| | | transport | | | | | |
| | | layer | | | | | |
| Exam. 3 | Coupled | Forming a | 3 μm | 500 | 40% | 550 mV | 3.0 μA/cm² |
| | Mass | Porous | | | | | |
| | of | Conductive | | | | | |
| | SnO₂ | Film | | | | | |
| | Particles | (Spin | | | | | |
| | | Coating) | | | | | |
| Exam. 4 | Coupled | Forming a | 10 μm | 2000 | 40% | 550 mV | 1.9 μA/cm² |
| | Mass | Porous | | | | | |
| | of | Conductive | | | | | |
| | SnO₂ | Film | | | | | |
| | Particles. | (Spin | | | | | |
| | | Coating) | | | | | |
| Exam. 5 | SnO₂ | Forming a | 1 μm | 200 | 80% | 550 mV | 3.3 μA/cm² |
| | Fibers | Porous | | | | | |
| | | Conductive | | | | | |
| | | Film | | | | | |
| | | (Electro- | | | | | |
| | | Spinning) | | | | | |
| Comp. | — | — | | 1.5 | — | 500 mV | 0.5 μA/cm² |
| Ex. 1 | | | | (in an | | | |
| | | | | electrode) | | | |

From the results in Table 1, it is found that Examples 1 to 5 existing the conductive agent 3 within the gel layer 2 are improved in photoelectric conversion rate by comparing with Comparative Example 1.

### DESCRIPTION OF THE SIGNS

1; Electron transport layer
2; Gel layer
3; Conductive agent
4; First electrode
5; Hole transport layer
6; Second electrode
7; First base plate
8; Second base plate
9; Conductive fiber

1. A photoelectric conversion element comprising:
a first electrode;
a second electrode;
a stack of an electron transport layer and hole transport layer, the stack being interposed between the first electrode and the second electrode;
an electrolyte solution; and
a conductive agent;
the electron transport layer containing an organic compound having a redox moiety causing repetitive oxidation-reduction reactions,
the electrolyte solution being selected to give stable reduction condition of the redox moiety,
the organic compound and the electrolyte solution being cooperative to form a gel layer,
wherein the conductive agent is present within the gal layer and kept at least partly in contact with the firsts electrode.

2. The photoelectric conversion element according to claim 1, wherein
the conductive agent has a roughness factor in the range of 5 to 2000.

3. The photoelectric conversion element according to claim 1, wherein
the conductive agent comprises a coupled mass of conductive particles.

4. The photoelectric conversion element according to claim 1, wherein
the conductive agent comprises conductive fibers.

5. The photoelectric conversion element according to claim 4, wherein
the conductive fibers have an average outside diameter in the range of 50 nm to 1000 nm.

6. The photoelectric conversion element according to claim 4, wherein
the conductive fibers have a void ratio of 50% to 95%.

7. The photoelectric conversion element according to claim 4, wherein
the conductive fibers have an average fiber length to average fiber diameter ratio of at least 1000.

8. The photoelectric conversion element according to claim 5, wherein
the conductive fibers have an average fiber length to average fiber diameter ratio of at least 1000.

9. The photoelectric conversion element according to claim 6, wherein
the conductive fibers have an average fiber length to average fiber diameter ratio of at least 1000.
